(19) United States
(12) Patent Application Publication
(10) Pub. No.: US 2012/0093189 A1
(43) Pub. Date: Apr. 19, 2012

(54) MULTIMODE VERTICAL-CAVITY SURFACE-EMITTING LASER ARRAYS

(76) Inventors: David A. Fattal, Mountain View, CA (US); Marco Fiorentino, Mountain View, CA (US); Raymond G. Beausoleil, Redmond, WA (US)

(21) Appl. No.: 13/259,857

(22) PCT Filed: Jan. 29, 2010
(86) PCT No.: PCT/US2010/022627

§ 371 Date: Sep. 23, 2011

(51) Int. Cl. H01S 5/026

(52) U.S. Cl. 372/50.11

(57) ABSTRACT

Various embodiments of the present invention are directed to monolithic VCSEL arrays where each VCSEL can be configured to lase at a different wavelength. In one embodiment, a monolithic surface-emitting laser array includes a reflective layer, a light-emitting layer (102), and a grating layer (112) configured with two or more non-periodic, sub-wavelength gratings. Each grating is configured to form a resonant cavity with the reflector, and each grating is configured with a grating pattern that shapes one or more internal cavity modes and shapes one or more external transverse modes emitted through the grating.

### TECHNICAL FIELD

Various embodiments of the present invention relate to lasers, and in particular, to semiconductor lasers.

### BACKGROUND

Semiconductor lasers represent one of the most important class of lasers in use today because they can be used in a wide variety of applications including displays, solid-state lighting, sensing, printing, and telecommunications just to name a few. The two types of semiconductor lasers primarily in use are edge-emitting lasers and surface-emitting lasers. Edge-emitting lasers generate light traveling in a direction substantially parallel to the light-emitting layer. On the other hand, surface-emitting lasers generate light traveling normal to the light-emitting layer. Surface-emitting layers have a number of advantages over typical edge-emitting lasers: they emit light more efficiently and can be arranged to form two-dimensional, light-emitting arrays.

Surface-emitting lasers configured with the light-emitting layer sandwiched between two reflectors are referred to as vertical-cavity surface-emitting lasers (“VCSELs”). The reflectors are typically distributed Bragg reflectors (“DBRs”) that ideally form a reflective cavity with greater than 99% reflectivity for optical feedback. DBRs are composed of multiple alternating layers, each layer composed of a dielectric or semiconductor material with periodic refractive index variation. Two adjacent layers within a DBR have different refractive indices and are referred to as “DBR pairs.” DBR reflectivity and bandwidth depend on the refractive-index contrast of constituent materials of each layer and on the thickness of each layer. The materials used to form DBR pairs typically have similar compositions and, therefore, have relatively small refractive-index differences. Thus, in order to achieve a cavity reflectivity of greater than 99%, and provide a narrow mirror bandwidth, DBRs are configured with anywhere from about 15 to about 40 or more DBR pairs. However, fabricating DBRs with greater than 99% reflectivity has proven to be difficult, especially for VCSELs designed to emit light with wavelengths in the blue-green and long-infrared portions of the electromagnetic spectrum.

Physicists and engineers continue to seek improvements in VCSEL design, operation, and efficiency.

### BRIEF DESCRIPTION OF THE DRAWINGS

FIG. 1A shows an isometric view of an example monolithic VCSEL array configured in accordance with one or more embodiments of the present invention.

FIG. 1B shows an exploded isometric view of the monolithic VCSEL array shown in FIG. 1A configured in accordance with one or more embodiments of the present invention.

FIG. 2 shows a cross-sectional view of the VCSEL array along a line A-A, shown in FIG. 1A, in accordance with one or more embodiments of the present invention.

FIGS. 3A-3C show top plan views of sub-wavelength gratings configured with one-dimensional and two-dimensional grating patterns in accordance with one or more embodiments of the present invention.

FIG. 4 shows a cross-sectional view of lines from two separate grating sub-patterns revealing the phase acquired by reflected light in accordance with one or more embodiments of the present invention.

FIG. 5 shows a cross-sectional view of lines from two separate grating sub-patterns revealing how the reflected wavefront changes in accordance with one or more embodiments of the present invention.

FIG. 6 shows an isometric view of an exemplary phase change contour map produced by a grating pattern configured in accordance with one or more embodiments of the present invention.

FIG. 7 shows a side view of a sub-wavelength grating configured to focus incident light to a focal point in accordance with one or more embodiments of the present invention.

FIG. 8 shows a plot of reflectance and phase shift over a range of incident light wavelengths for a sub-wavelength grating configured in accordance with one or more embodiments of the present invention.

FIG. 9 shows a phase contour plot of phase variation as a function of period and duty cycle obtained in accordance with one or more embodiments of the present invention.

FIG. 10A shows a top plan view of a one-dimensional sub-wavelength grating configured to operate as a focusing cylindrical mirror in accordance with one or more embodiments of the present invention.

FIG. 10B shows a top plan view of a one-dimensional sub-wavelength grating configured to operate as a focusing spherical mirror in accordance with one or more embodiments of the present invention.

FIGS. 11A-11B show cross-sectional views of a resonant cavity of a VCSEL array operated in accordance with one or more embodiments of the present invention.

FIG. 12 shows example plots of a hypothetical cavity modes and intensity or gain profile associated with a VCSEL array configured in accordance with one or more embodiments of the present invention.

FIG. 13 shows a plane-concave resonator that schematically represents the resonant cavity of a VCSEL in a VCSEL array configured in accordance with one or more embodiments of the present invention.

FIG. 14 shows various ways in which light can be emitted from VCSELs of a VCSEL array in accordance with one or more embodiments of the present invention.

FIGS. 15A-15B show an isometric and cross-sectional views along a line B-B of a second example VCSEL array configured in accordance with one or more embodiments of the present invention.

FIGS. 16A-16B show an isometric and cross-sectional view along a line C-C of a third example VCSEL array configured in accordance with one or more embodiments of the present invention.

FIG. 17 shows an isometric view of an example laser system configured in accordance with one or more embodiments of the present invention.

### DETAILED DESCRIPTION

Various embodiments of the present invention are directed to monolithic VCSEL arrays where each VCSEL can be configured to lase at a different wavelength. Each VCSEL within the VCSEL array includes one or more planar, non-periodic, sub-wavelength gratings (“SWGs”). The SWG of each VCSEL can be configured with a different grating configuration enabling each VCSEL to lase at a different wavelength. The SWG of each VCSEL can be configured to control the shape of internal cavity modes and the shape of external modes emitted from the VCSEL. Each VCSEL has a small mode volume, an approximately single spatial output mode, emits light over a narrow wavelength range, and can be configured to emit light with a single polarization.

In the following description, the term “light” refers to electromagnetic radiation with wavelengths in the visible and non-visible portions of the electromagnetic spectrum, including infrared and ultra-violet portions of the electromagnetic spectrum.

Note also that in the following description, for sake of simplicity and convenience, VCSEL array embodiments of the present invention are described as having a square arrangement of four VCSELs. However, embodiments of the present invention are not intended to be so limited. VCSEL array embodiments can actually be configured with any suitable number of VCSELs, and the VCSELs can have any suitable arrangement within the monolithic VCSEL array.

### Vertical-Cavity Surface-Emitting Arrays

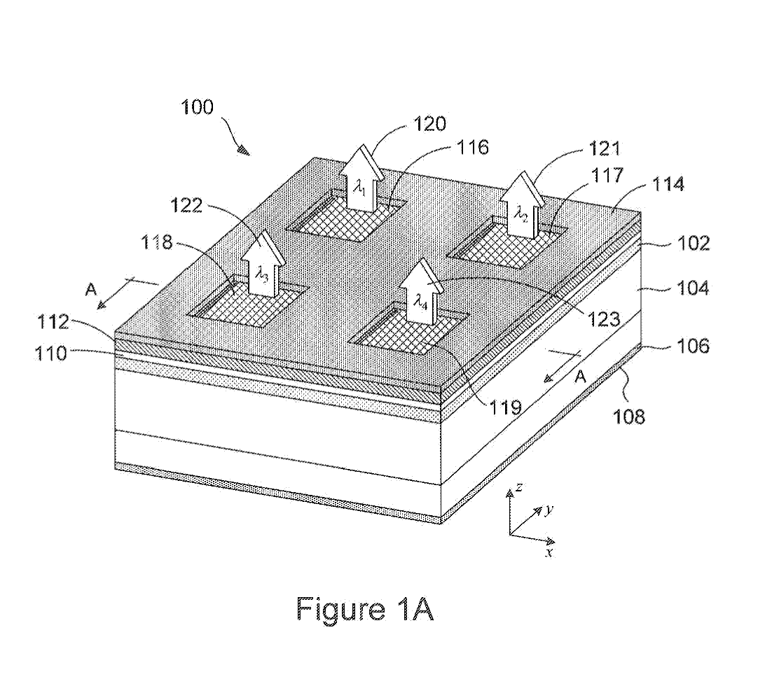

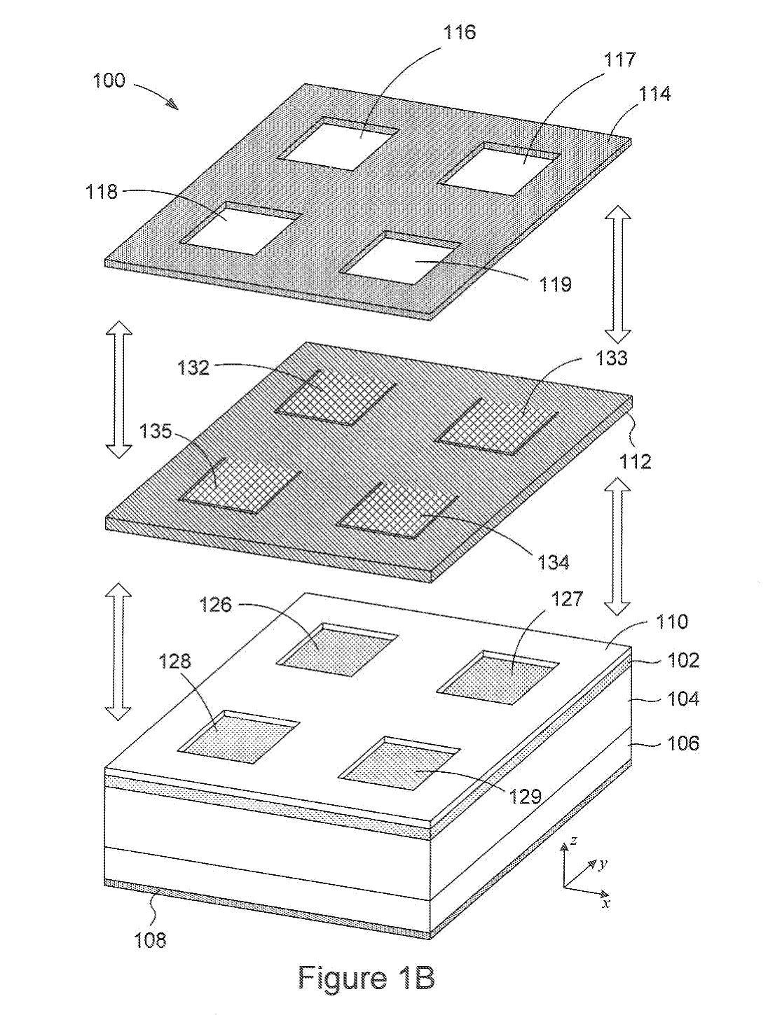

FIG. 1A shows an isometric view of an example monolithic VCSEL array 100 configured in accordance with one or more embodiments of the present invention. The VCSEL array 100 includes a light-emitting layer 102 disposed on a distributed Bragg reflector (“DBR”) 104. The DBR 104 is in turn disposed on a substrate 106 which is disposed on a first electrode 108. The VCSEL array 100 also includes an insulating layer 110 disposed on the light-emitting layer 102, a grating layer 112 disposed on the layer 110, and a second electrode 114 disposed on the grating layer 112. As shown in the example of FIG. 1A, the second electrode 114 is configured with four rectangular-shaped openings 116-119, each opening exposing a portion of the grating layer 112. Each opening allows longitudinal or axial modes of light emitted from the light-emitting layer 102 to exit the VCSEL substantially perpendicular to the xy-plane of the layers, as indicated by directional arrows 120-123 (i.e., longitudinal modes of light are emitted from the VCSEL array 100 through each opening in the z-direction).

FIG. 1B shows an exploded isometric view of the VCSEL array 100 configured in accordance with one or more embodiments of the present invention. The isometric view reveals four openings 126-129 in the insulating layer 110 and four SWGs 132-135 in the grating layer 112. The openings 126-129 allows light emitted from the light-emitting layer 102 to reach corresponding SWGs 132-135, respectively. Note that embodiments of the present invention are not limited to the openings 116-119 and 126-129 being rectangular shaped. In other embodiments, the openings in the second electrode and insulating layers can be square, circular, elliptical or any other suitable shape.

Note that each of the SWGs 116-119 defines a separate VCSEL within the monolithic VCSEL array 100. The four VCSELs defined by the SWGs 116-119 all share the same DBR 104 and light-emitting layer 102, except the SWGs 116-119 can each be configured to lase at different wavelengths. For example, as shown in FIG. 1A, SWGs 116-119 are configured to emit light with the wavelengths λ₁, λ₂, λ₃, and λ₄, respectively. As described in greater detail below, each SWG can be also be configured to emit light with a different polarization or emit unpolarized light.

The layers 104, 106, and 112 are composed of a various combinations of suitable compound semiconductor materials. Compound semiconductors include III-V compound semiconductors and II-VI compound semiconductors. III-V compound semiconductors are composed of column IIIa elements selected from boron (“B”), aluminum (“Al”), gallium (“Ga”), and indium (“In”) in combination with column Va elements selected from nitrogen (“N”), phosphorus (“P”), arsenic (“As”), and antimony (“Sb”). III-V compound semiconductors are classified according to the relative quantities of III and V elements, such as binary compound semiconductors, ternary compound semiconductors, quaternary compound semiconductors. For example, binary semiconductor compounds include, but are not limited to, GaAs, GaAl, InP, InAs, and GaP; ternary compound semiconductors include, but are not limited to, In_{y}Ga_{y-1}As or GaAs_{y}P_{1-y}, where y ranges between 0 and 1; and quaternary compound semiconductors include, but are not limited to, InₓGa₁₋ₓAs_{y}P_{1-y}, where both x and y independently range between 0 and 1. II-VI compound semiconductors are composed of column IIb elements selected from zinc (“Zn”), cadmium (“Cd”), mercury (“Hg”) in combination with VIa elements selected from oxygen (“O”), sulfur (“S”), and selenium (“Se”). For example, suitable II-VI compound semiconductors includes, but are not limited to, CdSe, ZnSe, ZnS, and ZnO are examples of binary II-VI compound semiconductors.

The layers of the VCSEL array 100 can be formed using chemical vapor deposition, physical vapor deposition, or wafer bonding. The SWGs 132-135 can be formed in the grating layer 112 using reactive ion etching, focusing beam milling, or nanoimprint lithography and the grating layer 112 bonded to the insulating layer 110.

In certain embodiments, the layers 104 and 106 are doped with a p-type impurity while the layer 112 is doped with an n-type impurity. In other embodiments, the layers 104 and 106 are doped with an n-type impurity while the layer 112 is doped with a p-type impurity. P-type impurities are atoms incorporated into the semiconductor lattice that introduce vacant electronic energy levels called “holes” to the electronic band gaps of the layers. These dopants are also called “electron acceptors.” On the other hand, n-type impurities are atoms incorporated into the semiconductor lattice that introduce filled electronic energy levels to the electronic band gaps of the layers. These dopants are called “electron donors.” In III-V compound semiconductors, column VI elements substitute for column V atoms in the III-V lattice and serve as n-type dopants, and column II elements substitute for column III atoms in the III-V lattice to serve as p-type dopants.

The insulating layer 110 can be composed of an insulating material, such SiO₂ or Al₂O₃ or another suitable material having a large electronic band gap. The electrodes 108 and 114 can be composed of a suitable conductor, such as gold (“Au”), silver (“Ag”), copper (“Cu”), or platinum (“Pt”).

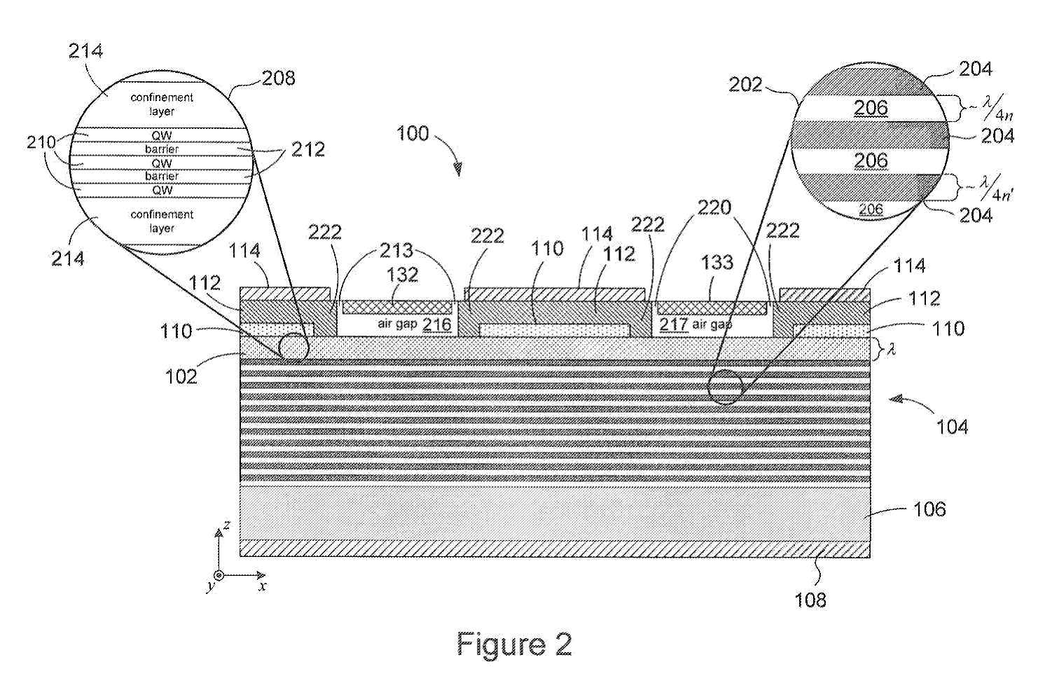

FIG. 2 shows a cross-sectional view of the VCSEL array 100 along a line A-A, shown in FIG. 1A, in accordance with one or more embodiments of the present invention. The cross-sectional view reveals the structure of the individual layers. The DBR 104 is composed of a stack of DBR pairs oriented parallel to the light-emitting layer 102. In practice, the DBR 104 can be composed of about 15 to about 40 or more DBR pairs. Enlargement 202 of a sample portion of the DBR 104 reveals that the layers of the DBR 104 each have a thickness of about λ/4 n and λ/4n′, where λ is the vacuum wavelength of light emitted from the light-emitting layer 102, and n is the index of refraction of the DBR layers 206 and n′ is the index of refraction of the DBR layers 204. Dark shaded layers 204 represent DBR layers composed of a first semiconductor material, and light shaded layers 206 represent DBR layers composed of a second semiconductor material, with the layers 204 and 206 having different associated refractive indices. For example, layers 204 can be composed of GaAs, which has an approximate refractive index of 3.6, layers 206 can be composed AlAs, which has an approximate refractive index of 2.9, and the substrate 106 can be composed of GaAs or AlAs.

FIG. 2 also includes an enlargement 208 of the light-emitting layer 102 that reveals one or many possible configurations for the layers comprising the light-emitting layer 102. Enlargement 208 reveals the light-emitting layer 102 is composed of three separate quantum-well layers (“QW”) 210 separated by barrier layers 212. The QWs 210 are disposed between confinement layers 214. The material comprising the QWs 210 has a smaller electronic band gap than the barrier layers 212 and confinement layers 214. The thickness of the confinement layers 214 can be selected so that the overall thickness of the light-emitting layer 102 is approximately the wavelength of the light emitted from the light-emitting layer 102. The layers 210, 212, and 214 are composed of different intrinsic semiconductor materials. For example, the QW layers 210 can be composed of InGaAs (e.g., Ino_{0.2}Ga_{0.8}As), the barrier layers 212 can be composed of GaAs, and the confinement layers can be composed of GaAlAs. Embodiments of the present invention are not limited to the light-emitting layer 102 having three QWs. In other embodiments, the light-emitting layer can have one, two, or more than three QWs.

FIG. 2 also reveals the configuration of the grating layer 112. The SWGs 132 and 133 are thinner that the rest of the grating layer 112 and are suspended above the light-emitting layer 112 in order to create air gaps 216 and 217 between the SWGs 132 and 133 and the light-emitting layer 112. As shown in FIG. 2, and in FIG. 1B, the SWGs 132-135 can be attached to the grating layer 112 along one edge with air gaps separating the three remaining edges of the SWGs 132-135 from the grating layer 112. For example, as shown in FIG. 2, air gaps 218 separate SWG 132 from the grating layer 112 and air gaps 220 separate SWG 133 from the grating layer 112. The grating layer 112 and the insulating layer 110 are also configured so that portions 222 of the grating layer 112 are in contact with the light-emitting layer 102 through the openings in the insulating layer 110. The insulating layer 110 constrains the flow of current through the portions 222 of the grating layer 112. The SWGs 132-135 and the DBR 104 are the reflectors that form reflective cavities for optical feedback during lasing of each VCSEL of the VCSEL array 100. For example, SWG 132 and DBR 104 form an optical cavity of a first VCSEL of the VCSEL array 100 and SWG 133 and DBR 104 form an optical cavity of a second VCSEL of the VCSEL array 100. SWGs 134 and 135 also form separate optical cavities with the DBR 104, the optical cavities associated with a third and a fourth VCSEL of the VCSEL array 100.

### Non-Periodic Sub-Wavelength Gratings

As described above, the SWGs 132-135 of the grating layer 112 are implemented as a suspended planar membranes above of the light-emitting layer 102. A SWG configured in accordance with one or more embodiments of the present invention provides reflective functionalities including control of the shape of the wavefront of the light reflected back into the corresponding cavity of the VCSEL array 100 and control of the shape of the wavefront of the light emitting through the corresponding opening in the second electrode 114, shown in FIG. 1A. This can be accomplished by configuring each SWG with a non-periodic, sub-wavelength grating pattern that controls the phase of the light reflected from the SWG without substantially affecting the high reflectivity of the SWG. In certain embodiments, as described below, a SWG can be configured with a grating pattern enabling the SWG to be operated as a cylindrical mirror or a spherical mirror.

Note that for the sake of simplicity, in the following description, configuring only one SWG of a grating layer is described. In practice, the grating layer may actually include numerous SWGs, and each SWG of the grating layer can be configured as described below.

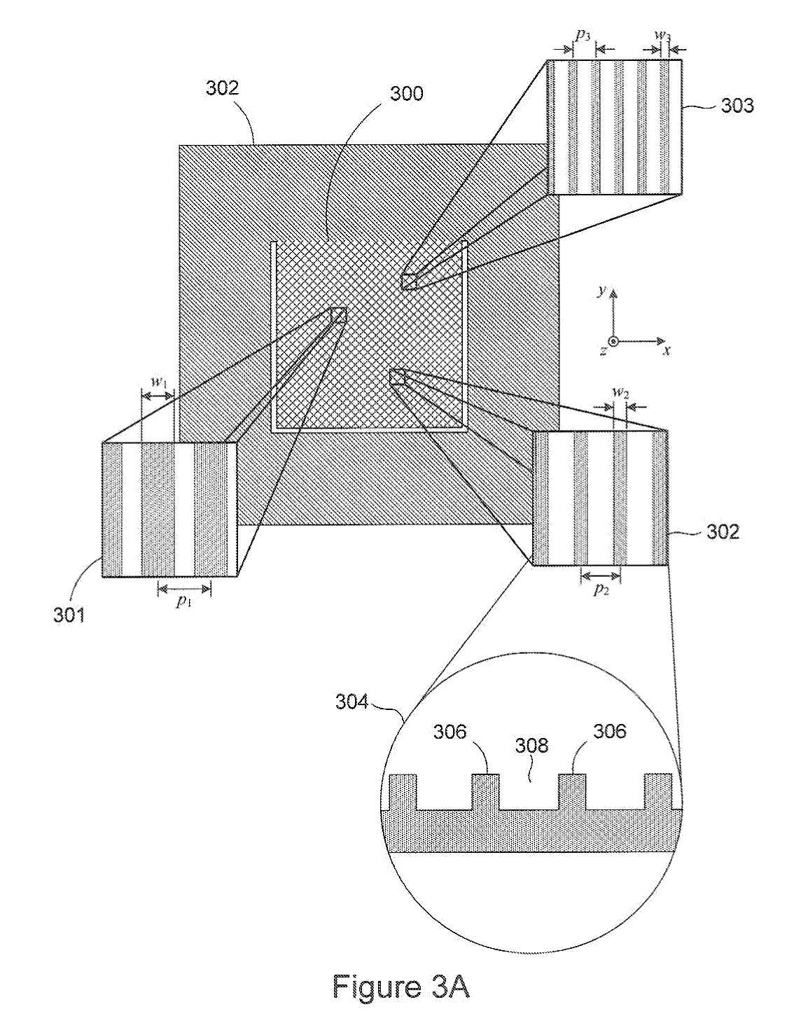

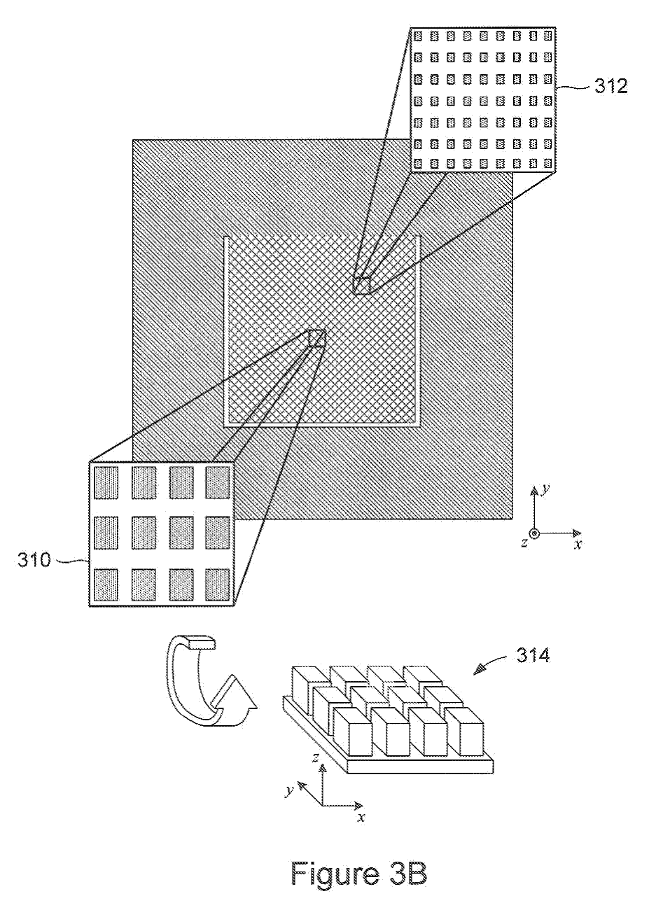

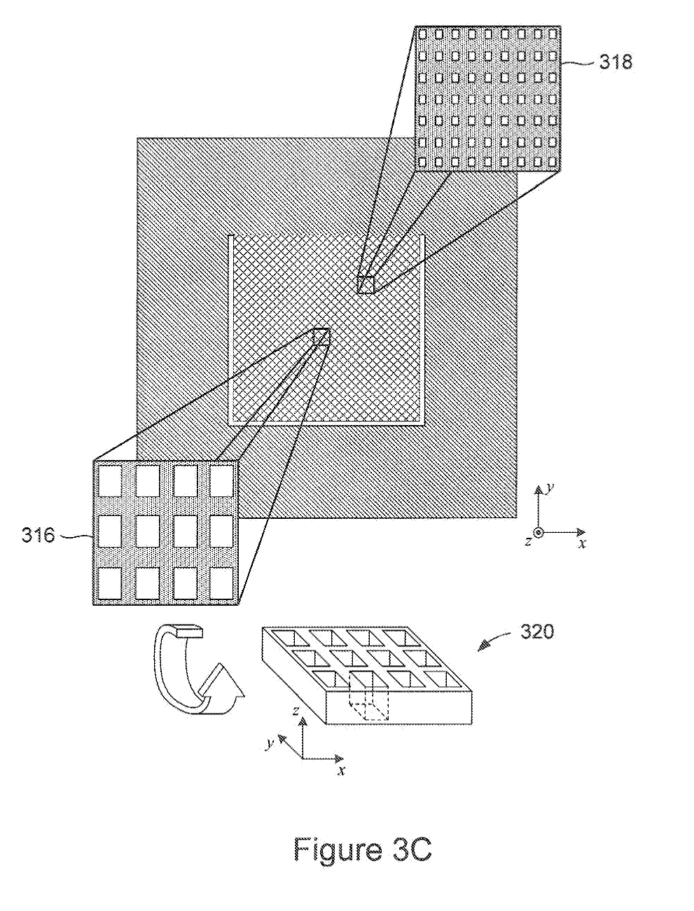

FIG. 3A shows a top plan view of a SWG 300 configured with a one-dimensional grating pattern formed in a grating layer 302 in accordance with one or more embodiments of the present invention. The one-dimensional grating pattern is composed of a number of one-dimensional grating sub-patterns. In the example of FIG. 3A, three grating sub-patterns 301-303 are enlarged. In the embodiment represented in FIG. 3A, each grating sub-pattern comprises a number of regularly spaced wire-like portions of the grating layer 102 material called “lines” formed in the grating layer 302. The lines extend in the y-direction and are periodically spaced in the x-direction. FIG. 3A also includes an enlarged end-on view 304 of the grating sub-pattern 302. The lines 306 are separated by grooves 308. Each sub-pattern can be characterized by a particular periodic spacing of the lines and by the line width in the x-direction. For example, the sub-pattern 301 comprises lines of width w₁ separated by a period p₁, the sub-pattern 302 comprises lines with width w₂ separated by a period p₂, and the sub-pattern 303 comprises lines with width w₃ separated by a period p₃.

The grating sub-patterns 301-303 form sub-wavelength gratings that preferentially reflect incident light polarized in one direction, i.e., the x-direction, provided the periods p₁, p₂, and p₃ are smaller than the wavelength of the incident light. For example, the lines widths can range from approximately 10 nm to approximately 300 nm and the periods can range from approximately 20 nm to approximately 1 μm depending on the wavelength of the incident light. The light reflected from a region acquires a phase φ determined by the line thickness t, and the duty cycle η defined as:

$$η = \frac{w}{p}$$

where w is the line width and p is the period spacing of the lines.

The SWG 300 can be configured to apply a particular phase change to reflected light while maintaining a very high reflectivity. The one-dimensional SWG 300 can be configured to reflect the x-polarized component or the y-polarized component of the incident light by adjusting the period, line width and line thickness of the lines. For example, a particular period, line width and line thickness may be suitable for reflecting the x-polarized component but not for reflecting the y-polarized component; and a different period, line width and line thickness may be suitable for reflecting the y-polarized component but not for reflecting the x-polarized component.

Embodiments of the present invention are not limited to one-dimensional gratings. A SWG can be configured with a two-dimensional, non-periodic grating pattern to reflect polarity insensitive light. FIGS. 3B-3C show top plan views of two example planar SWGs with two-dimensional, non-periodic, sub-wavelength grating patterns in accordance with one or more embodiments of the present invention. In the example of FIG. 3B, the SWG is composed of posts rather lines separated by grooves. The duty cycle and period can be varied in the x- and y-directions. Enlargements 310 and 312 show top views of two different rectangular-shaped post sizes. FIG. 3B includes an isometric view 314 of posts comprising the enlargement 310. Embodiments of the present invention are not limited to rectangular-shaped posts, in other embodiments the posts can be square, circular, elliptical or any other suitable shape. In the example of FIG. 3C, the SWG is composed of holes rather than posts. Enlargements 316 and 318 show two different rectangular-shaped hole sizes. The duty cycle can be varied in the x- and y-directions. FIG. 3C includes an isometric view 320 comprising the enlargement 316. Although the holes shown in FIG. 3C are rectangular shaped, in other embodiments, the holes can be square, circular, elliptical or any other suitable shape.

In other embodiments, the line spacing, thickness, and periods can be continuously varying in both one- and two-dimensional grating patterns.

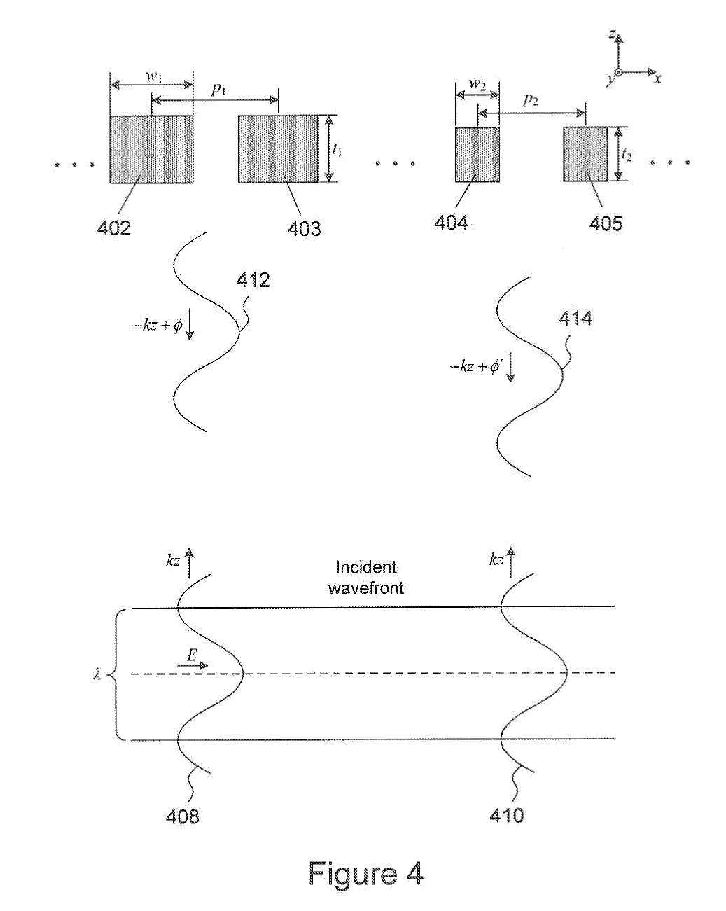

Each of the grating sub-patterns 301-303 of the SWG 300 also reflects incident light polarized in one direction, say the x-direction, differently due to the different duty cycles and periods associated with each of the sub-patterns. FIG. 4 shows a cross-sectional view of lines from two separate grating sub-patterns revealing the phase acquired by reflected light in accordance with one or more embodiments of the present invention. For example, lines 402 and 403 can be lines in a first grating sub-pattern located in the SWG 400, and lines 404 and 405 can be lines in a second grating sub-pattern located elsewhere in the SWG 400. The thickness t₁ of the lines 402 and 403 is greater than the thickness t₂ of the lines 404 and 405, and the duty cycle η₁ associated with the lines 402 and 403 is also greater than the duty cycle η₂ associated with the lines 404 and 405. Light polarized in the x-direction and incident on the lines 402-405 becomes trapped by the lines 402 and 403 for a relatively longer period of time than the portion of the incident light trapped by the lines 404 and 405. As a result, the portion of light reflected from the lines 402 and 403 acquires a larger phase shift than the portion of light reflected from the lines 404 and 405. As shown in the example of FIG. 4, the incident waves 408 and 410 strike the lines 402-405 with approximately the same phase, but the wave 412 reflected from the lines 402 and 403 acquires a relatively larger phase shift φ than the phase φ′ (i.e., φ>φ′) acquired by the wave 414 reflected from the lines 404 and 405.

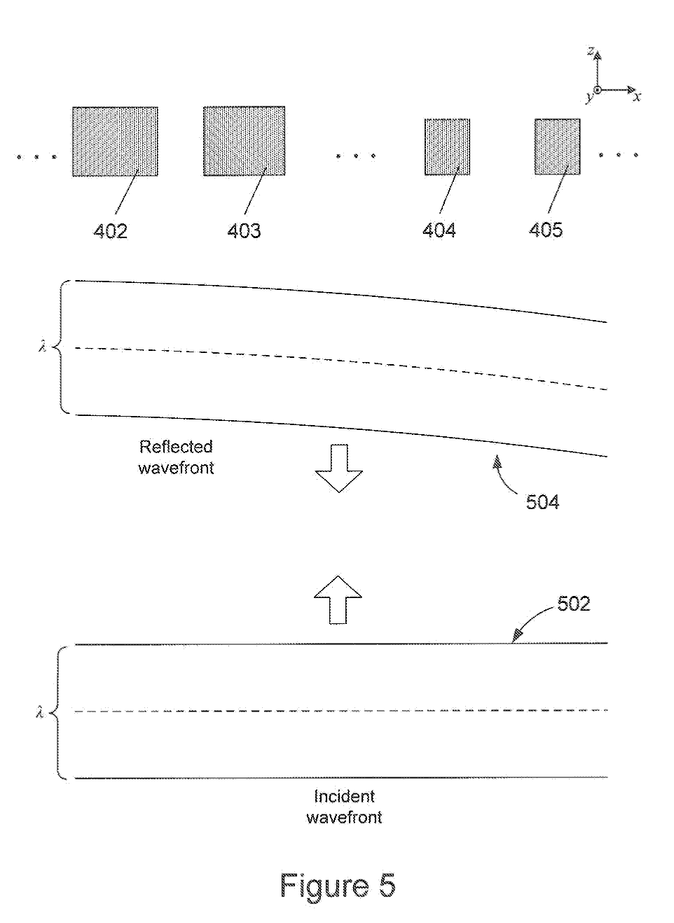

FIG. 5 shows a cross-sectional view of the lines 402-405 revealing how the reflected wavefront changes in accordance with one or more embodiments of the present invention. As shown in the example of FIG. 5, incident light with a substantially uniform wavefront 502 strikes the lines 402-405 producing reflected light with a curved reflected wavefront 504. The curved reflected wavefront 504 results from portions of the incident wavefront 502 interacting with the lines 402 and 403 with a relatively larger duty cycle η₁ and thickness t₁ than portions of the same incident wavefront 502 interacting with the lines 404 and 405 with a relatively smaller duty cycle η₂ and thickness t₂. The shape of the reflected wavefront 504 is consistent with the larger phase acquired by light striking the lines 402 and 403 relative to the smaller phase acquired by light striking the lines 404 and 405.

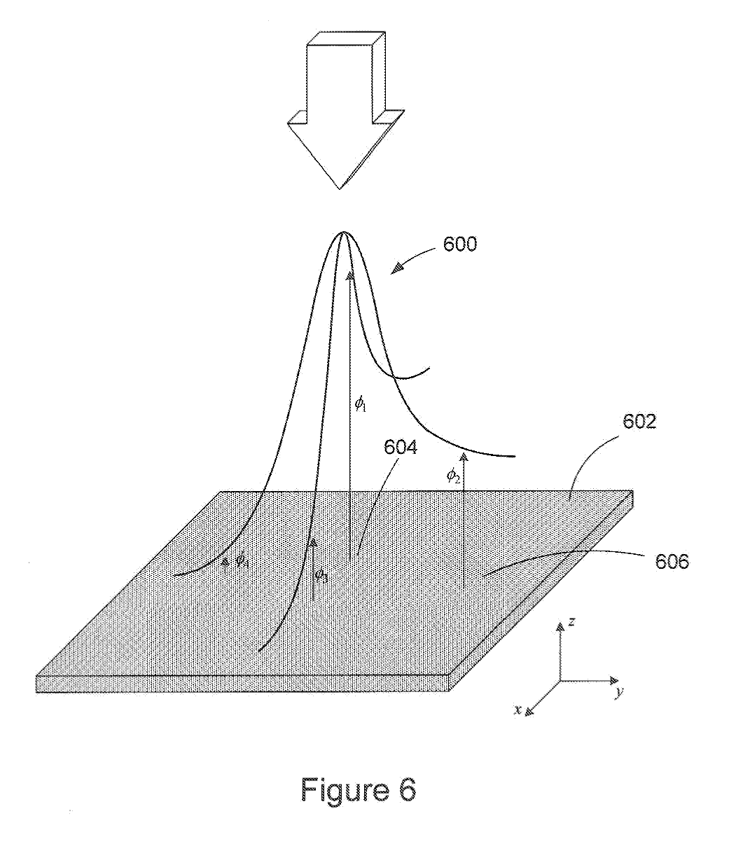

FIG. 6 shows an isometric view of an exemplary phase change contour map 600 produced by a particular grating pattern of a SWG 602 in accordance with one or more embodiments of the present invention. The contour map 600 represents the magnitude of the phase change acquired by light reflected from the SWG 602. In the example shown in FIG. 6, the grating pattern of the SWG 602 produces a contour map 602 with the largest magnitude in the phase acquired by the light reflected near the center of the SWG 602, with the magnitude of the phase acquired by reflected light decreasing away from the center of the SWG 602. For example, light reflected from a sub-pattern 604 acquires a phase of φ₁, and light reflected from a sub-pattern 606 acquires a phase of φ₂. Because φ₁ is much larger than φ₂, the light reflected from the sub-pattern 606 acquires a much larger phase than the light reflected from the sub-pattern 608.

The phase change in turn shapes the wavefront of light reflected from a SWG. For example, as described above with reference to FIGS. 4 and 5, lines having a relatively larger duty cycle produce a larger phase shift in reflected light than lines having a relatively smaller duty cycle. As a result, a first portion of a wavefront reflected from lines having a first duty cycle lags behind a second portion of the same wavefront reflected from a different set of lines configured with a second relatively smaller duty cycle. Embodiments of the present invention include patterning the SWG to control the phase change and ultimately the shape of the reflected wavefront so that the SWG can be operated as a mirror with particular optical properties, such as a focusing mirror.

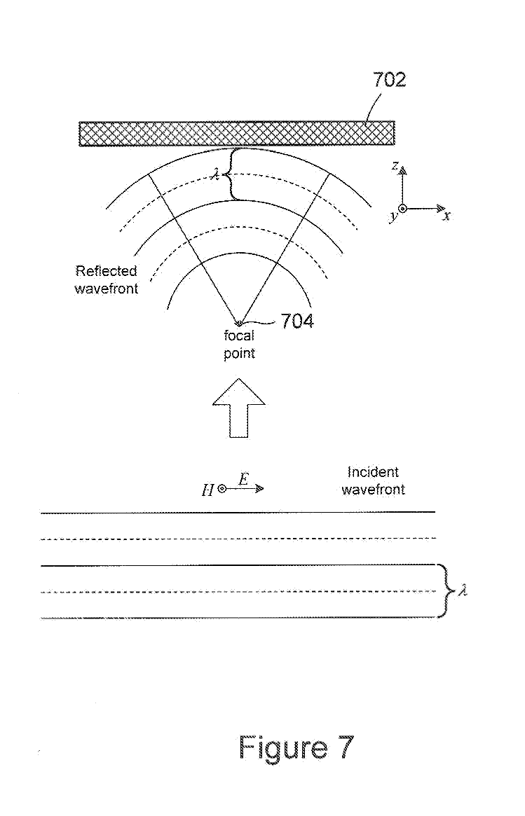

FIG. 7 shows a side view of a SWG 702 configured to operate as a focusing mirror in accordance with one or more embodiments of the present invention. In the example of FIG. 7, the SWG 702 is configured with a grating pattern so that incident light polarized in the x-direction is reflected with a wavefront corresponding to focusing the reflected light at the focal point 704.

### Configuring Non-Periodic Sub-Wavelength Gratings

Embodiments of the present invention include a number of ways in which each SWG of a grating layer can be configured to operate as a mirror. A first method for configuring a SWG to reflect light with a desired wavefront includes determining a reflection coefficient profile for the grating layer of the SWG. The reflection coefficient is a complex valued function represented by:

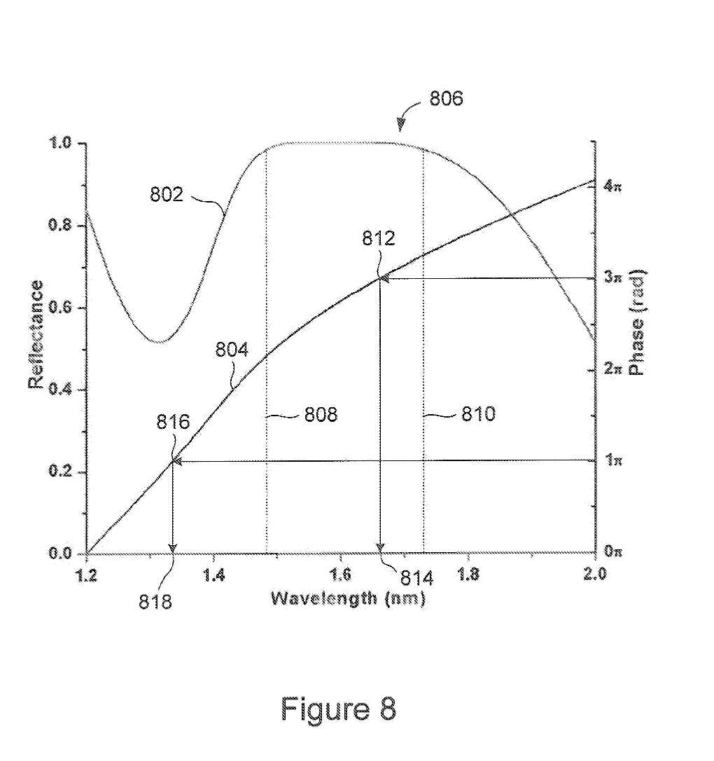

r(λ)=\sqrt{R(λ)e^{iφ(λ)}}

where R(λ) is the reflectance of the SWG, and φ(λ) is the phase shift or phase change produced by the SWG. FIG. 8 shows a plot of reflectance and phase shift over a range of incident light wavelengths for an example SWG in accordance with one or more embodiments of the present invention. In this example, the grating layer is configured with a one-dimensional grating and is operated at normal incidence with the electric field component polarized perpendicular to the lines of the grating layer. In the example of FIG. 8, curve 802 corresponds to the reflectance R(λ) and curve 804 corresponds to the phase shift φ(λ) produced by the SWG for the incident light over the wavelength range of approximately 1.2 μm to approximately 2.0 μm. The reflectance and phase curves 802 and 804 can be determined using either the well-known finite element method or rigorous coupled wave analysis. Due to the strong refractive index contrast SWG and air, the SWG has a broad spectral region of high reflectivity 806. However, curve 804 reveals that the phase of the reflected light vanes across the entire high-reflectivity spectral region between dashed-lines 808 and 810.

When the spatial dimensions of the period and width of the lines is changed uniformly by a factor α, the reflection coefficient profile remains substantially unchanged, but with the wavelength axis scaled by the factor α. In other words, when a grating has been designed with a particular reflection coefficient R₀ at a free space wavelength λ₀, a new grating with the same reflection coefficient at a different wavelength λ can be designed by multiplying all the grating geometric parameters, such as the period, line thickness, and line width, by the factor α=λ/λ₀, giving r(λ)=r₀(λ/α)=r₀(λ₀).

In addition, a grating can be designed with |R(λ)|→1, but with a spatially varying phase, by scaling the parameters of the original periodic grating non-uniformly within the high-reflectivity spectral window 806. Suppose that introducing a phase φ(x,y) on a portion of light reflected from a point on the SWG with transverse coordinates (x,y) is desired. Near the point (x,y), a non-uniform grating with a slowly varying grating scale factor α(x,y) behaves locally as though the grating was a periodic grating with a reflection coefficient R₀(λ/α). Thus, given a periodic grating design with a phase φ₀ at some wavelength λ₀, choosing a local scale factor α(x,y)=λ/λ₀ gives φ(x,y)=φ₀ at the operating wavelength λ. For example, suppose that introducing a phase of approximately 3π on a portion of the light reflected from a point (x,y) on a SWG design is desired, but the line width and period selected for the point (x,y) introduces a phase of approximately π. Referring again to the plot in FIG. 8, the desired phase φ₀=3π corresponds to the point 812 on the curve 804 and the wavelength λ₀=1.67 μm 814, and the phase π associated with the point (x,y) corresponds to the point 816 on the curve 804 and the wavelength λ=1.34 μm. Thus the scale factor is α(x,y)=λ/λ₀=1.34/1.67=0.802, and the line width and period at the point (x,y) can be adjusted by multiplying by the factor α in order to obtain the desired phase φ₀=3π at the operating wavelength λ=1.34 μm.

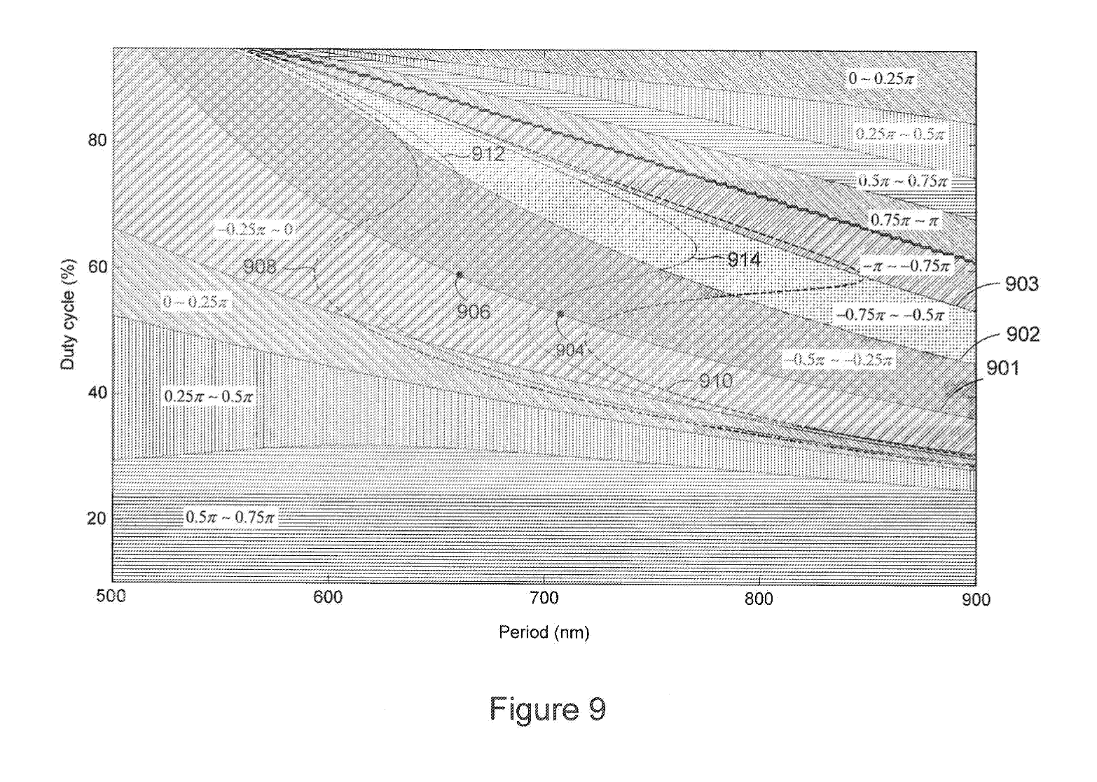

The plot of reflectance and phase shift versus a range of wavelengths shown in FIG. 8 represents one way in which parameters of a SWG, such as line width, line thickness and period, can be determined in order to introduce a particular phase to light reflected from a particular point of the SWG. In other embodiments, phase variation as a function of period and duty cycle can be used to construct a SWG. FIG. 9 shows a phase contour plot of phase variation as a function of period and duty cycle that can be used to configure a SWG in accordance with one or more embodiments of the present invention. The contour plot shown in FIG. 9 can be produced using either the well-known finite element method or rigorous coupled wave analysis. Contour lines, such as contour lines 901-903, each correspond to a particular phase acquired by light reflected from a grating pattern with a period and duty cycle lying anywhere along the contour. The phase contours are separated by 0.25π rad. For example, contour 901 corresponds periods and duty cycles that apply a phase of −0.25π rad to reflected light, and contour 902 corresponds to periods and duty cycles that apply a phase of −0.5π rad to reflected light. Phases between −0.25π rad and −0.5π rad are applied to light reflected from a SWG with periods and duty cycles that lie between contours 901 and 902. A first point (p,η) 904, corresponding to a grating period of 700 nm and 54% duty cycle, and a second point (p,η) 906, corresponding to a grating period of 660 nm and 60% duty cycle, both lie on the contour 901 and produce the same phase shift −0.25π but with different duty cycles and line period spacing.

FIG. 9 also includes two reflectivity contours for 95% and 98% reflectivity overlain on the phase contour surface. Dashed-line contours 908 and 910 correspond to 95% reflectivity, and solid line contours 912 and 914 correspond to 98% reflectivity. Points (p,η,φ) that lie anywhere between the contours 908 and 910 have a minimum reflectivity of 95%, and points (p,η,φ) that lie anywhere between the contours 912 and 914 have a minimum reflectivity of 98%.

The points (p,η,φ) represented by the phase contour plot can be used to select periods and duty cycles for a grating that can be operated as a particular type of mirror with a minimum reflectivity, as described below in the next subsection. In other words, the data represented in the phase contour plot of FIG. 9 can be used to design SWG optical devices. In certain embodiments, the period or duty cycle can be fixed while the other parameter is varied to design and fabricate SWGs. In other embodiments, both the period and duty cycle can be varied to design and fabricate SWGs.

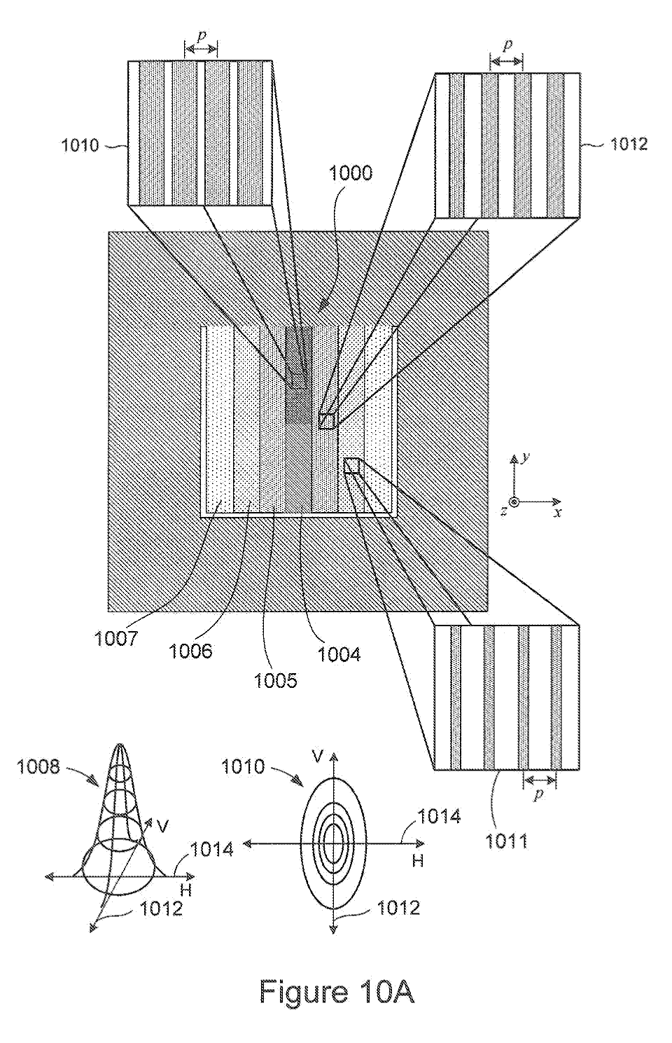

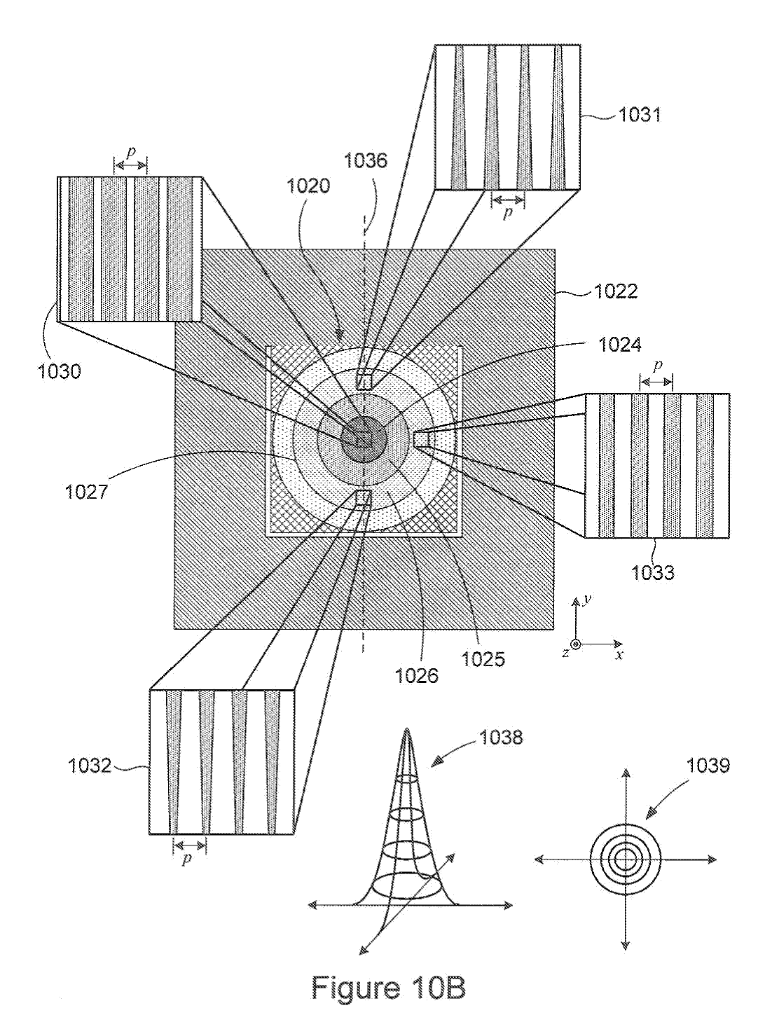

In certain embodiments, a SWG of a grating layer can be configured to operate as a cylindrical mirror with a constant period and variable duty cycle. FIG. 10A shows a top plan view of a one-dimensional SWG 1000 formed in a grating layer 1002 and configured to operate as a focusing cylindrical mirror for incident light polarized parallel to the x-direction in accordance with one or more embodiments of the present invention. FIG. 10A includes shaded regions, such as shaded regions 1004-1007, each shaded region representing a different duty cycle with darker shaded regions, such as region 1004, representing regions with a relatively larger duty cycle than lighter shaded regions, such as region 1007. FIG. 10A also includes enlargements 1010-1012 of sub-regions revealing that the lines are parallel in the y-direction and the line period spacing p is constant or fixed in the x-direction. Enlargements 1010-1012 also reveal that the duty cycle η decreases away from the center. The SWG 1000 is configured to focus reflected light polarized in the x-direction to a focal point, as described above with reference to FIG. 7A. FIG. 10A also includes example isometric and top view contour plots 1008 and 1010 of reflected beam profiles at the foci. V-axis 1012 is parallel to the y-direction and represents the vertical component of the reflected beam, and H-axis 1014 is parallel to the x-direction and represents the horizontal component of the reflected beam. The reflected beam profiles 1008 and 1010 indicate that for incident light polarized in the x-direction, the SWG 1000 reflects a Gaussian-shaped beam that is narrow in the direction perpendicular to the lines (the “H” of x-direction) and broad in the direction parallel to the lines (the “V” or y-direction).

In certain embodiments, a SWG with a constant period can be configured to operate as a spherical mirror for incident polarized light by tapering the lines of the grating layer away from the center of the SWG. FIG. 10B shows a top plan view of a one-dimensional SWG 1020 formed in a grating layer 1022 and configured to operate as a focusing spherical mirror for incident light polarized in the x-direction in accordance with one or more embodiments of the present invention. The SWG 1020 defines a circular mirror aperture. The grating pattern of the SWG 1020 is represented by annular shaded regions 1024-1027. Each shaded annular region represents a different grating sub-pattern of lines. Enlargements 1030-1033 reveal that the lines are tapered in the y-direction with a constant line period spacing p in the x-direction. In particular, enlargements 1030-1032 are enlargements of the same lines running parallel to dashed-reference line 1036 in the y-direction. Enlargements 1030-1032 show that the period p is fixed. Each annular region has the same duty cycle η. For example, enlargements 1031-1033 comprise portions of different lines within the annular region 1026 that have substantially the same duty cycle. As a result, each portion of an annular region imparts the same approximate phase shift in the light reflected from the annular region. For example, light reflected from anywhere within the annular region 1026 acquires substantially the same phase shift φ. FIG. 10B also includes example isometric and top view contour plots 1038 and 1039 of reflected beam profiles at the foci. The beam profiles 1038 and 1039 reveal that the spherical SWG 1020 produces a symmetrical Gaussian-shaped reflected beam and is narrower in the V- or x-direction than the reflected beam of the SWG 1000.

The SWGs 1000 and 1020 represent just two or many different kinds of SWGs of a grating layer that can be configured in accordance with one or more embodiments of the present invention. Each SWG of a grating layer can be configured with different reflective properties.

### Laser Operation and Cavity Configurations

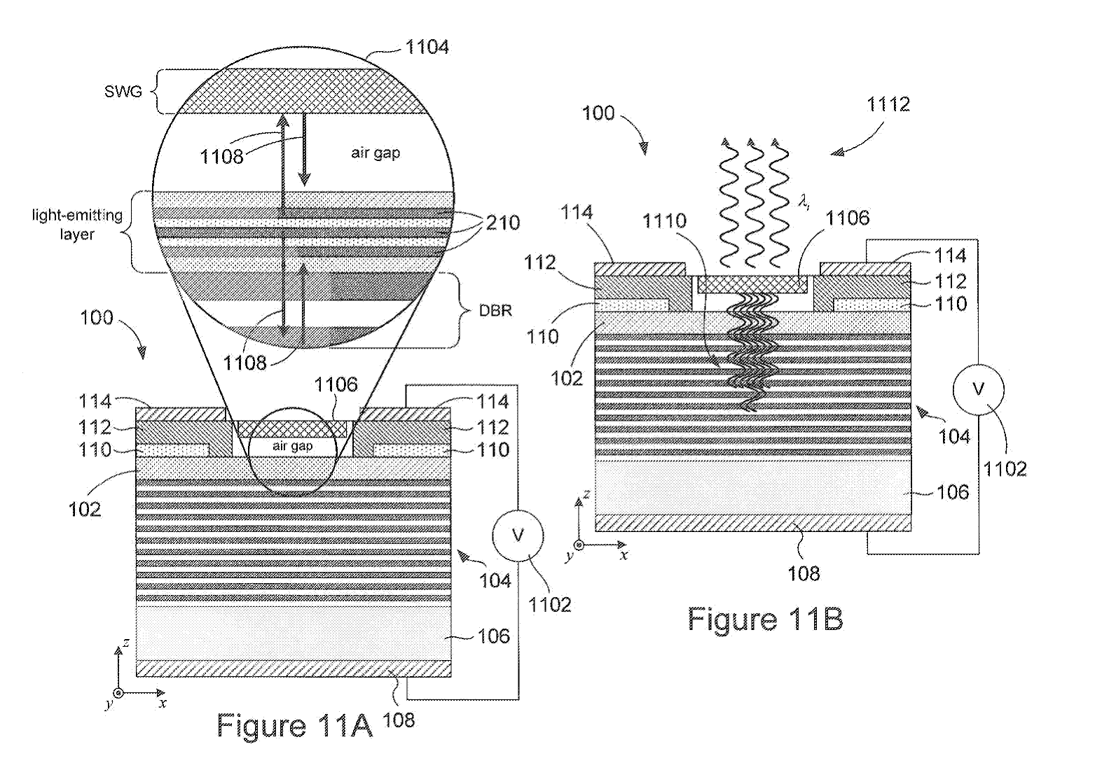

Because each VCSEL of a VCSEL array is operated in the same manner, the operation of only one VCSEL of the VCSEL array 100 is described. FIGS. 11A-11B show cross-sectional views of one resonant cavity of the VCSEL array 100 operated in accordance with one or more embodiments of the present invention. As shown in FIG. 11A, the electrodes 114 and 108 are electronically coupled to a voltage source 1102 used to electronically pump the light-emitting layer 102. FIG. 11A includes an enlargement 1104 of a portion of a SWG 1106, the air gap 1108, a portion of the light-emitting layer 102, and a portion of the DBR 104. The SWG 1106 represents one of the SWGs 132-135. When no bias is applied to the VCSEL array 100, the QWs 210 have a relatively low concentration of electrons in corresponding conduction bands and a relatively low concentration of vacant electronic states, or holes, in corresponding valence bands and substantially no light is emitted from the light-emitting layer 102. On the other hand, when a forward-bias is applied across the layers of the VCSEL array 100, electrons are injected into the conduction bands of the QWs 210 while holes are injected into the valence bands of the QWs 210, creating excess conduction band electrons and excess valence band holes in a process referred to as population inversion. The electrons in the conduction band spontaneously recombine with holes in the valence band in a radiative process called “electron-hole recombination” or “recombination.” When electrons and holes recombine, light is initially emitted in all directions over a range of wavelengths. As long as an appropriate operating voltage is applied in the forward-bias direction, electron and hole population inversion is maintained at the QWs 210 and electrons can spontaneously recombine with holes, emitting light in nearly all directions.

As described above, the SWG 1106 and the DBR 104 can be configured to form a cavity that reflects light emitted substantially normal to the light-emitting layer 102 and over a narrow range of wavelengths back into the light-emitting layer 102, as indicated by directional arrows 1108. The light reflected back into the QWs 210 stimulates the emission of more light from the QWs 210 in a chain reaction. Note that although the light-emitting layer 102 initially emits light over a range of wavelengths via spontaneous emission, the SWG 1106 selects a wavelength, λᵢ, where i equals 1, 2, 3, or 4, to reflect back into the light-emitting layer 102 causing stimulated emission. This wavelength is referred to as the longitudinal, axial, or z-axis mode. Over time, the gain becomes saturated by the longitudinal mode and longitudinal mode begins to dominate the light emissions from the light-emitting layer 102 and other longitudinal modes decay. In other words, light that is not reflected back and forth between the SWG 1106 and the DBR 104 leaks out of the VCSEL array 100 with no appreciable amplification and eventually decays as the longitudinal mode supported by the cavity begins to dominate. The dominant longitudinal mode reflected between the SWG 1106 and the DBR 104 is amplified as it sweeps back and forth across the light-emitting layer 102 producing standing waves 1110 that terminate within the SWG 1106 and extend into the DBR 104, as shown in FIG. 11B. Ultimately, a substantially coherent beam of light 1112 with the wavelength λᵢ emerges from the SWG 1106. Light emitted from the light-emitting layer 102 penetrates the DBR 104 and the SWG 1106 and adds a contribution to the round trip phase of the light in the cavity. The DBR 104 and the SWG 1106 can be thought of as perfect mirrors that shift in space to provide an effective extra phase shift.

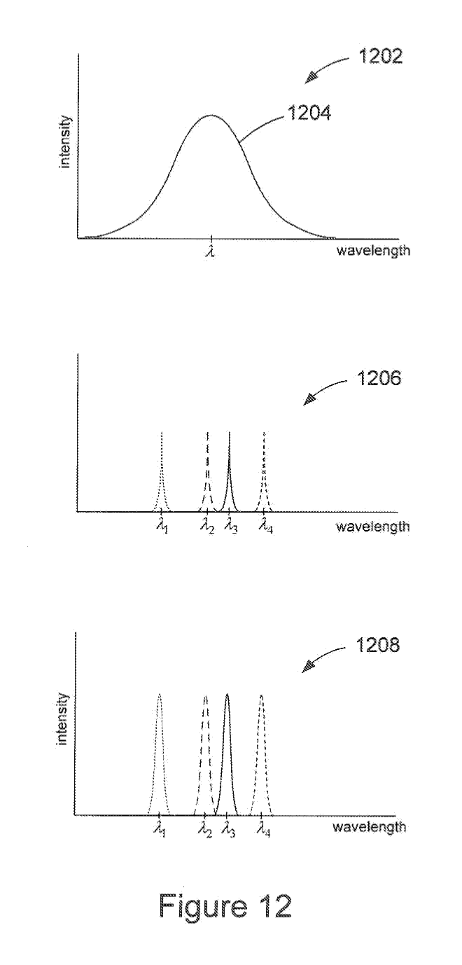

Each SWG of a VCSEL array can be configured to select a different longitudinal mode of light emitted from the light-emitting layer 102. FIG. 12 shows an example plot 1202 of an intensity or gain profile 1204 of light emitted from the light-emitting layer 102 centered about a wavelength λ in accordance with one or more embodiments of the present invention. FIG. 12 includes an example plot 1206 of four different single cavity modes, each single cavity mode associated with a different VCSEL or the VCSEL array 100. For example, peaks in the plot 1206 represent single longitudinal cavity modes λ₁, λ₂, λ₃, and λ₄ that are associated with the four cavities formed by SWG 132-135 and the DBR 104, respectively. The light-emitting layer 102 emits and makes available a broad range of wavelengths represented by the intensity profile 1204 out of which the cavity associated with each VCSEL selects one of the longitudinal single cavity modes represented in plot 1206. Each longitudinal mode is amplified within the cavity of the associated VCSEL and emitted as described above with reference to FIG. 11. For example, plot 1208 shows the intensity profiles of wavelengths emitted from the four VCSELs of the VCSEL array 100. As shown in plot 1208, each longitudinal mode can be emitted with substantially the same intensity.

Note that although the VCSEL array is described as emitting a different wavelength for each VCSEL, embodiments of the present invention are not intended to be so limited. In other embodiments, any combination of VCSELs, including all of the VCSELs of the VCSEL array, can be configured to emit the same wavelength.

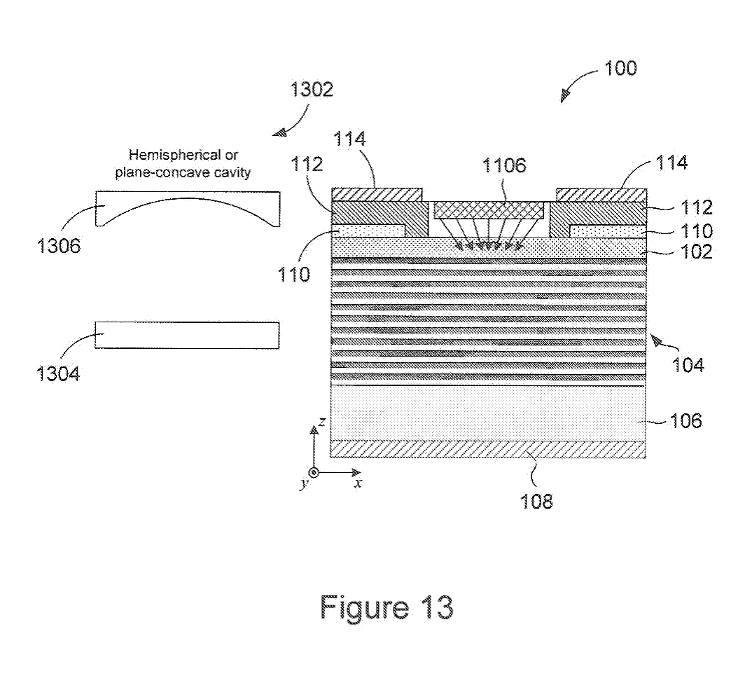

As described above in the preceding subsection Configuring Non-periodic Sub-wavelength Gratings, each SWG of a grating layer can be configured to shape the internal longitudinal or z-axis cavity modes and operate as a concave mirror. FIG. 13 shows a plane-concave resonator 1302 that schematically represents a configuration of the resonant cavity of a VCSEL in the VCSEL array 100 in accordance with one or more embodiments of the present invention. The plane-concave resonator 1302 includes a planar mirror 1304 and a concave mirror 1306. The DBR 104 of the VCSEL array 100 corresponds to the planar mirror 1304, and the SWG 1106 can be configured as described above to operate as a concave mirror that reflects light so that the light is concentrated within a region of the light-emitting layer 102 between the SWG 1106 and the DBR 104. For example, the SWG 1106 can be configured to reflect light with the intensity profiles represented in FIGS. 10A and 10B.

The VCSELs of the VCSEL array can each be configured to emit different polarized cavity modes. For example, certain VCSELs can be configured to emit light polarized in different directions while other VCSELs can be configured to emit unpolarized light. As described above in the preceding subsection Configuring Non-periodic Sub-wavelength Gratings, a SWG can be configured to reflect light polarized substantially perpendicular to the lines and grooves of the SWG. In other words, the SWG of a resonant cavity also selects the component of the light emitted from the light-emitting layer with a particular polarization. The polarization component of the light emitted from the light-emitting layer is selected by the SWG and reflected back into the cavity. As the gain becomes saturated, only longitudinal modes with the polarization selected by the SWG are amplified. The longitudinal modes emitted from the light-emitting layer that are not selected by the SWG leak out of the VCSEL array 100 with no appreciable amplification. In other words, modes with polarizations other than those selected by the SWG decay and are not amplified by the cavity. Ultimately, only modes polarized in the direction selected by the SWG are emitted from the VCSEL array.

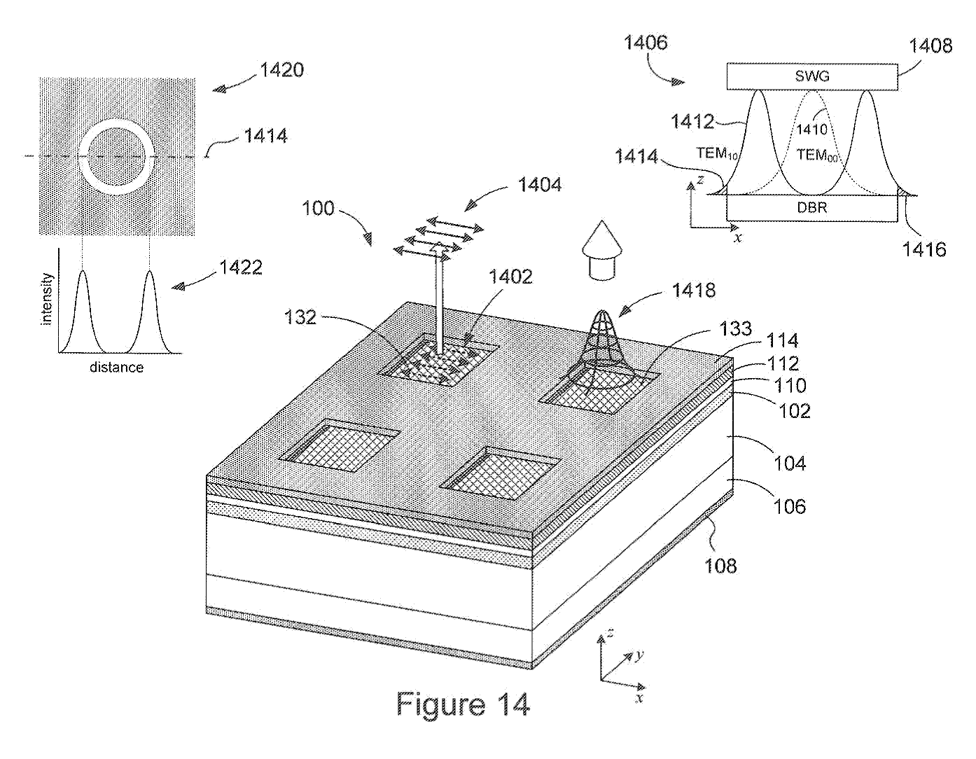

FIG. 14 shows an example of polarized light emitted from one VCSEL of the VCSEL array 100 in accordance with one or more embodiments of the present invention. Light emitted from the light-emitting layer 102 is unpolarized. However, over time, as the gain saturates, a polarization state is selected by the SWG 132. Double-headed arrows 1402 incident on the SWG 132 from within the VCSEL array 100 represent a polarization state selected by the SWG 132. SWG 132 can be configured as described above with lines and grooves running parallel to the y-direction. In the example of FIG. 14, the SWG 132 selects only the longitudinal mode emitted from the light-emitting layer 102 that is polarized in the x-direction. The polarized light is amplified within the cavity formed by the SWG 132 and the DBR 104 as described above with reference to FIG. 11. As shown in the example of FIG. 14, the light emitted through the SWG 132 is polarized in the x-direction, as represented by double-headed arrows 1404.

In addition to supporting particular longitudinal or axial modes of oscillation, which correspond to standing waves supported by the cavity along the z-axis, transverse modes can be supported by each cavity as well. Transverse modes are normal to the cavity or z-axis and are known as TEMₙₘ modes, where m and n subscripts are the integer number of transverse nodal lines in the x- and y-directions across the emerging beam. In other words, the beam formed within the cavity can be segmented in its cross section into one or more regions. A SWG can be configured to only support one or certain transverse modes.

FIG. 14 also shows an example of two transverse modes created in a cavity 1406 formed by a SWG 1408 and the DBR 104 in accordance with one or more embodiments of the present invention. The SWG 1408 can represent any one of the SWGs 132-135. As described above, the SWG 1408 can be configured to define the size of the cavity. As shown in FIG. 14, the TEM₀₀ mode, is represented by dotted curve 1410 and the TEM₁₀ mode is represented by solid curve 1412. The TEM₀₀ mode has no nodes and lies entirely within the cavity 1406. On the other hand, the TEM₁₀ mode has one node in the x-direction and portions 1414 and 1416 lie outside the cavity 1406. As a result, during gain saturation, because the TEM₀₀ mode lies entirely within the cavity 1406, TEM₀₀ mode is amplified. However, because portions of the TEM₁₀ mode lie outside the cavity 1406, the TEM₁₀ mode decreases during gain saturation and eventually decays, while the TEM₀₀ mode continues to amplify. Other TEMₘₙ modes that cannot be supported by, or lie entirely within, the cavity 1406 also decay.

FIG. 14 shows a contour plot 1418 of the intensity profile of TEM₀₀ emitted from one VCSEL of the VCSEL array 100 in accordance with one or more embodiments of the present invention. The TEM₀₀ emerges from the SWG 133 with a nearly planar coherent wavefront and with a Gaussian transverse irradiance profile represented by the contour plot 1418. The intensity profile is symmetrical about the z-axis. The external TEM₀₀ mode corresponds to an internal TEM₀₀ mode can be produced by the SWG 133 configured to operate as a spherical mirror as described above with reference to FIG. 10B. In other embodiments, the SWG 133 can be configured to operate as a cylindrical mirror that produces a lowest order transverse mode TEM₀₀ that is narrow in the direction perpendicular to the lines of the SWG 133 (the x-direction) and broad in the direction parallel to the lines of the SWG 133 (the y-direction), as described above with reference to FIG. 10A. The TEM₀₀ mode can be coupled into the core of an optical fiber by placing the fiber so that core of the fiber is located in close proximity to the SWG 133. The SWG 133 can also be configured to emit transverse modes that are suitable for coupling into hollow waveguides, such as the EH₁₁ mode of a hollow waveguide.

The SWGs can be configured to generate beams of light with particular intensity profile patterns. FIG. 14 shows an example cross-sectional view 1420 of a beam of light emitted from a VCSEL. The cross-sectional view 1420 reveals a beam of light with a donut-shaped intensity profile along the length of the beam. Intensity profile 1422 of the emitted beam along the line 1424 reveals a cylindrical-shaped beam. The SWGs can be configured to generate other kinds of cross-sectional beam patterns, such as an Airy beam or a Bessel beam profile.

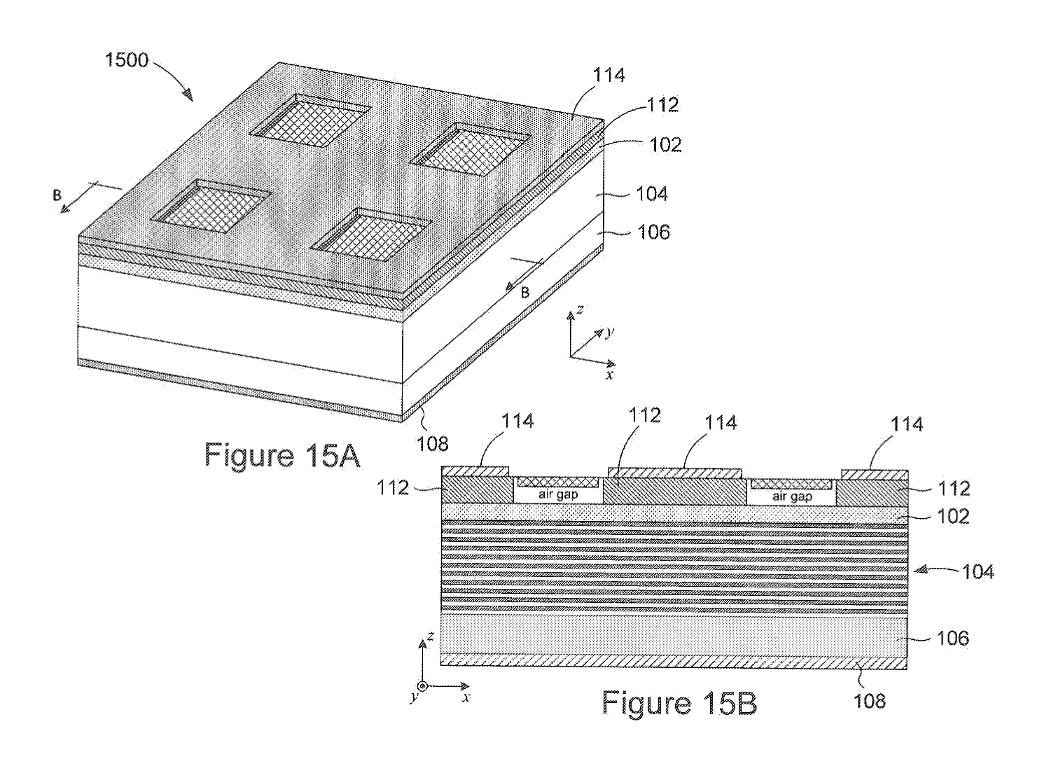

Returning to FIGS. 1 and 2, the insulating layer 110 is configured to provide current and optical confinement. However, VCSEL array embodiments of the present invention are not limited to including the insulating layer 110 because the SWG can be configured to confine reflected light to a region of the light-emitting layer located between the SWG and the DBR, as described above with reference to FIG. 13. FIGS. 15A-15B show an isometric and cross-sectional view along a line B-B of an example VCSEL array 1500 configured in accordance with one or more embodiments of the present invention. The VCSEL array 1500 is similar to the VCSEL array 100 except the insulting layer 110 of the VCSEL array 100 is not present in the VCSEL array 1500. Instead, each SWG of the grating layer 112 is configured to direct reflected light into a region of the light-emitting layer 102 located between the SWG and the DBR 104.

Note that the height and cavity length of VCSEL configured in accordance with embodiments of the present invention is considerably shorter than the height and cavity length of a conventional VCSEL configured with two DBRs. For example, a typical VCSEL DBR has anywhere from about 15 to about 40 DBR pairs corresponding to about 5 μm to about 6 μm, while a SWG may have a thickness ranging from about 0.2 μm to about 0.3 μm and has an equivalent or higher reflectivity.

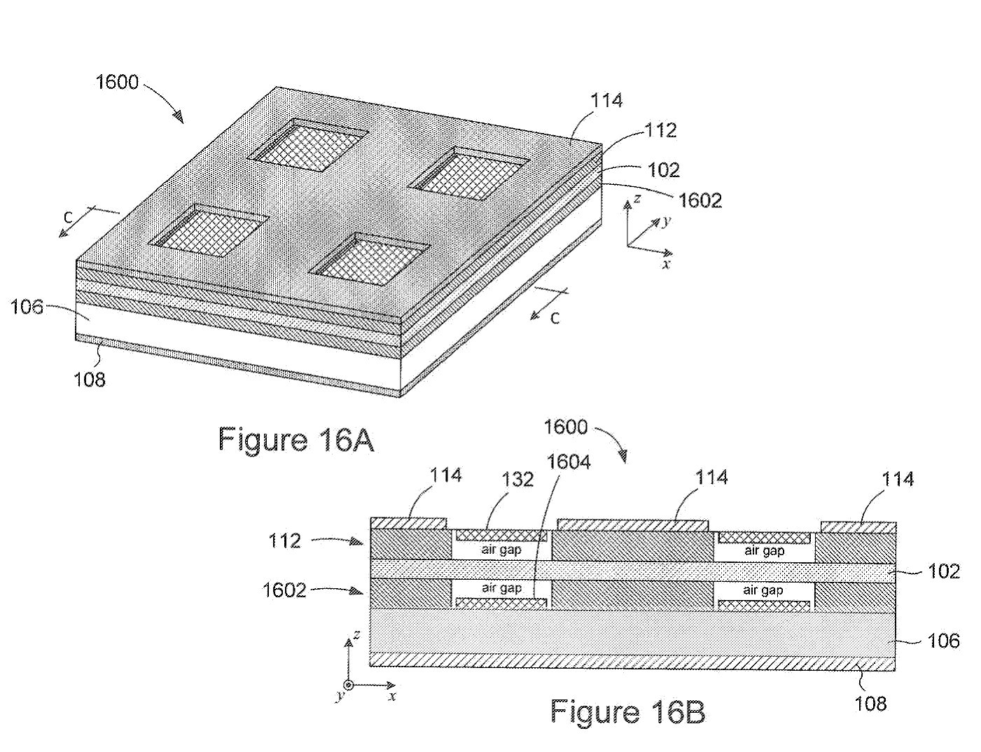

In still other embodiments of the present invention, the height of the VCSEL array can be further reduced by using two grating layers. FIGS. 16A-16B show an isometric and cross-sectional view along a line C-C of an example VCSEL array 1600 configured in accordance with one or more embodiments of the present invention. The VCSEL array 1600 is similar to the VCSEL array 100 except the DBR 104 is replaced by a second grating layer 1602. As shown in FIG. 16B, the SWGs of the gratings layers 112 and 1602 are aligned to form cavity resonators. For example, SWGs 132 and 1604 form a cavity resonator. The SWGs of the grating layer 1602 can be configured with either a one-dimensional or two-dimensional grating pattern to operate in the same manner as the SWGs of the grating layer 112 described above. The SWG pairs of the grating layers can be configured operate as a spherical cavity to direct reflected light into a region of the light-emitting layer 102, potentially eliminating the need for insulating layer 110.

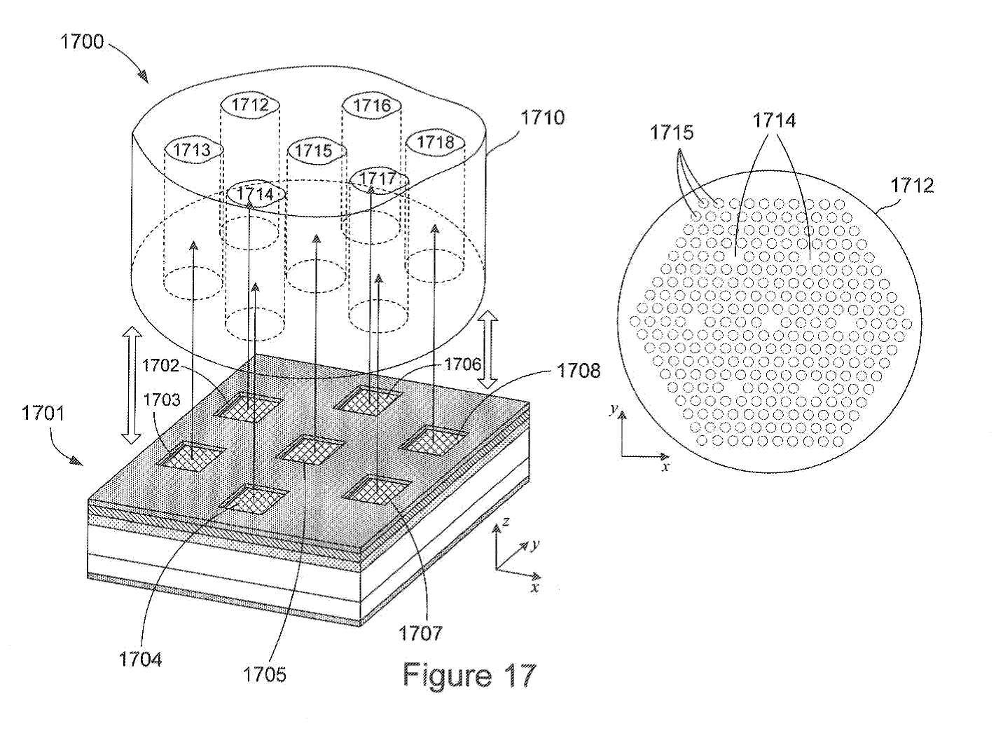

Embodiments of the present invention include laser systems for transmitting the wavelengths of light output from each VCSEL of a VCSEL array into a waveguide. FIG. 17 shows an isometric view of an example laser system 1700 configured in accordance with one or more embodiments of the present invention. The system 1700 includes a monolithic VCSEL array 1701 comprising seven VCSELs 1702-1708 and a multiple waveguide fiber 1710 comprising seven waveguides 1712-1718. As shown in the example of FIG. 17, the seven VCSELs 1702-1708 are arranged to match the configuration of the waveguides 1712-1718 so that light emitted from each waveguide can be coupled directly into a waveguide as indicated by directional arrows. For example, the waveguides can be single mode cores of an optical fiber and the VCSELs 1702-1708 can be configured to output a single mode, such as TEM₀₀ as described above with reference to FIG. 14, that couple directly into a corresponding core.

In certain embodiments, the fiber 1710 can be a photonic crystal fiber. FIG. 17 includes an end-on-view of a photonic crystal fiber 1712 comprising seven cores 1714. Each core is surrounded by hollow tubes 1715 that span the length of the fiber. The hollow tubes 1714 serve as cladding layers that confine light to the higher refractive index cores 1714. In order to couple light into the cores of the fiber 1712, the VCSEL array 1701 can be configured so that the VCSELs 1702-1708 are aligned with the cores 1714 of the fiber 1712.

In other embodiments, rather than using a photonic crystal fiber to carry light generated by a VCSEL array, a bundle of hollow waveguides can be also be used provided the VCSELs are configured to output modes of light that match the modes supported by the hollow waveguides.

The foregoing description, for purposes of explanation, used specific nomenclature to provide a thorough understanding of the invention. However, it will be apparent to one skilled in the art that the specific details are not required in order to practice the invention. The foregoing descriptions of specific embodiments of the present invention are presented for purposes of illustration and description. They are not intended to be exhaustive of or to limit the invention to the precise forms disclosed. Obviously, many modifications and variations are possible in view of the above teachings. The embodiments are shown and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents:

1. A monolithic surface-emitting laser array comprising:
a reflective layer;
a light-emitting layer (102); and
a grating layer (112) configured with two or more non-periodic, sub-wavelength gratings, wherein each grating is configured to form a resonant cavity with the reflector, and each grating is configured with a grating pattern that shapes one or more internal cavity modes and shapes one or more external transverse modes emitted through the grating.

2. The laser array of claim 1 further comprises:
a substrate (106) disposed on the reflective layer;
a first electrode (108) disposed on the substrate, and
a second electrode (114) disposed on the grating layer, the second electrode configured with two or more openings, each opening configured to expose one of the two or more sub-wavelength gratings.

3. The laser array of claim 1 wherein the reflective layer further comprises a distributed Bragg reflector (104).

4. The laser array of claim 1 wherein the reflective layer further comprises a second grating layer (1602) configured with a two or more non-periodic, sub-wavelength gratings (1604), wherein each sub-wavelength grating in the second grating layer is aligned with one or the to or more sub-wavelength gratings in the grating layer.

5. The laser array of claim 1 or 4 wherein the grating pattern further comprises a one-dimensional pattern of lines separated by grooves (300).

6. The laser array of claim 1 or 4 wherein the grating pattern comprises a two-dimensional grating pattern.

7. The laser array of claim 1 wherein each sub-wavelength grating further comprises a suspended membrane (132,133) that forms an air gap (216,217) between the sub-wavelength grating and the light-emitting layer.

8. The laser array of claim 1 further comprising an insulating layer (110) disposed between the light-emitting layer and the grating layer, wherein the insulting layer includes two or more openings (126-128) aligned with the sub-wavelength gratings for current and optical confinement of light emitted from the light-emitting layer.

9. The laser array of claim 1 wherein the light amplified within, and emitted from, each resonant cavity is polarized or unpolarized based on the grating pattern of each corresponding sub-wavelength grating.

10. The laser array of claim 1 wherein two or more sub-wavelength gratings of the grating layer are configured to form a single mode resonant cavity for emitting a single mode of light.

11. The laser array of claim 1 wherein each sub-wavelength grating configured with a grating pattern that shapes one or more internal cavity modes further comprises a grating pattern resulting in a beam of light having a donut-shaped intensity cross section.

12. The laser array of claim 1 wherein one or more of the sub-wavelength gratings can be configured to form a hemispherical cavity (1302) with the reflector.

13. A laser system (1700) comprising:
a monolithic surface-emitting laser array (1701) including two or more surface-emitting layers configured in accordance with claim 1; and
a multiple waveguide fiber (1710), wherein each waveguide is aligned with a surface-emitting laser of the laser array such that light emitted from each surface-emitting layer is coupled into and transmitted by a corresponding waveguide.

14. The laser system of claim 13 wherein the multiple waveguide fiber further comprises a photonic crystal fiber (1710) configured with multiple cores (1714), each core aligned with a surface-emitting laser of the laser array.

15. The laser system of claim 13 wherein the multiple waveguide fiber further comprises a bundle of hollow waveguides, each hollow waveguide aligned with a surface-emitting laser of the laser array.
